(19) United States
(12) Patent Application Publication
(10) Pub. No.: US 2024/0371664 A1
(43) Pub. Date: Nov. 7, 2024

(54) CHIP TRANSFERRING AND BONDING DEVICE

(71) Applicant: ASTI GLOBAL INC., TAIWAN, Taichung City (TW)

(72) Inventors: CHIEN-SHOU LIAO, Taichung City (TW); YING-CHIEH CHEN, Taichung City (TW)

(21) Appl. No.: 18/626,284

(22) Filed: Apr. 3, 2024

Related U.S. Application Data
(60) Provisional application No. 63/463,894, filed on May 4, 2023.
(60) Provisional application No. 63/521,751, filed on Jun. 19, 2023.
(60) Provisional application No. 63/521,759, filed on Jun. 19, 2023.
(60) Provisional application No. 63/544,417, filed on Oct. 16, 2023.

(51) Int. Cl. H01L 21/67; H01L 21/683; H01L 23/00

(52) U.S. Cl. CPC H01L 21/67144; H01L 21/6838; H01L 24/75; H01L 2224/75252; H01L 2224/7598

(57) ABSTRACT

A chip transferring and bonding device includes a signal control module, a substrate carrying module, a chip transferring module and a chip bonding module. The substrate carrying module is configured to be electrically connected to the signal control module. The chip transferring module is configured to be electrically connected to the signal control module. The chip bonding module is configured to be electrically connected to the signal control module. The chip bonding module includes at least one micro heater, and the at least one micro heater of the chip bonding module is a light source generator configured for generating a light source or a heat source generator configured for generating a heat source. When the chip bonding module is optionally configured to be used, the micro heater of the chip bonding module can be allowed to heat a corresponding one of the chips through the signal control module.

### CROSS-REFERENCE TO RELATED PATENT APPLICATION

This application claims the benefit of priorities to the U.S. Provisional Patent Application Ser. No. 63/463,894, filed on May 4, 2023, No. 63/521,751, filed on Jun. 19, 2023, No. 63/521,759, filed on Jun. 19, 2023, and No. 63/544,417 filed on Oct. 16, 2023, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a chip transferring and bonding device, and more particularly to a chip transferring and bonding device using a light source generator or a heat source generator.

### BACKGROUND OF THE DISCLOSURE

In the related art, multiple chips need to be bonded on the circuit board by soldering. However, there is still room for improvement in the related art of the chip bonding device and the chip bonding method.

### SUMMARY OF THE DISCLOSURE

In response to the above-referenced technical inadequacy, the present disclosure provides a chip transferring and bonding device.

In order to solve the above-mentioned problems, one of the technical aspects adopted by the present disclosure is to provide a chip transferring and bonding device, which includes a signal control module, a substrate carrying module, a chip transferring module and a chip bonding module. The substrate carrying module is configured to be electrically connected to the signal control module. The chip transferring module is configured to be electrically connected to the signal control module. The chip bonding module is configured to be electrically connected to the signal control module, and the chip bonding module includes at least one micro heater. When the substrate carrying module is optionally configured to be used, the substrate carrying module is allowed to be configured to carry a circuit substrate through the signal control module. When the chip transferring module is optionally configured to be used, the chip transferring module is allowed to be configured to carry a temporary carrying substrate that is configured for carrying a plurality of chips through the signal control module. When the chip transferring module is optionally configured to be used, the chip transferring module is allowed to be configured to transfer the chips that are carried by the temporary carrying substrate to the circuit substrate through the signal control module. When the chip bonding module is optionally configured to be used, the at least one micro heater of the chip bonding module is allowed to heat a corresponding one of the chips through the signal control module.

In order to solve the above-mentioned problems, another one of the technical aspects adopted by the present disclosure is to provide a chip transferring and bonding device, which includes a signal control module, a substrate carrying module, a chip transferring module and a chip bonding module. The substrate carrying module is configured to be electrically connected to the signal control module. The chip transferring module is configured to be electrically connected to the signal control module. The chip bonding module is configured to be electrically connected to the signal control module. The chip bonding module includes at least one micro heater, and the at least one micro heater of the chip bonding module is a light source generator configured for generating a light source or a heat source generator configured for generating a heat source.

In order to solve the above-mentioned problems, yet another one of the technical aspects adopted by the present disclosure is to provide a chip transferring and bonding device, which includes a signal control module, a substrate carrying module, a chip transferring module and a chip bonding module. The substrate carrying module is configured to be electrically connected to the signal control module. The chip transferring module is configured to be electrically connected to the signal control module. The chip bonding module is configured to be electrically connected to the signal control module, and the chip bonding module includes at least one micro heater. When the substrate carrying module is optionally configured to be used, the substrate carrying module is allowed to be configured to carry the chip bonding module through the signal control module. When the chip bonding module is optionally configured to be used, the chip bonding module is configured to carry a temporary carrying substrate that is configured for carrying a plurality of chips. When the chip transferring module is optionally configured to be used, the chip transferring module is allowed to be configured to carry a circuit substrate through the signal control module. When the chip transferring module is optionally configured to be used, the chip transferring module is allowed to be configured to transfer the circuit substrate to the chips that are carried by the temporary carrying substrate through the signal control module. When the chip bonding module is optionally configured to be used, the at least one micro heater of the chip bonding module is allowed to heat a corresponding one of the chips through the signal control module.

Therefore, in the chip transferring and bonding device provided by the present disclosure, by virtue of “the substrate carrying module being configured to be electrically connected to the signal control module,” “the chip transferring module being configured to be electrically connected to the signal control module” and “the chip bonding module being configured to be electrically connected to the signal control module, and the chip bonding module including at least one micro heater,” when the chip transferring module is optionally configured to be used, the chip transferring module is allowed to be configured to transfer the chips that are carried by the temporary carrying substrate to the circuit substrate through the signal control module, and when the chip bonding module is optionally configured to be used, the at least one micro heater of the chip bonding module is allowed to heat a corresponding one of the chips through the signal control module.

Furthermore, in the chip transferring and bonding device provided by the present disclosure, by virtue of “the substrate carrying module being configured to be electrically connected to the signal control module,” “the chip transferring module being configured to be electrically connected to the signal control module,” “the chip bonding module being configured to be electrically connected to the signal control module, and the chip bonding module including at least one micro heater” and “the at least one micro heater of the chip bonding module being configured as a light source generator configured for generating a light source or a heat source generator configured for generating a heat source,” when the chip transferring module is optionally configured to be used, the chip transferring module is allowed to be configured to transfer the chips that are carried by the temporary carrying substrate to the circuit substrate through the signal control module, and when the chip bonding module is optionally configured to be used, the at least one micro heater of the chip bonding module is allowed to heat a corresponding one of the chips through the signal control module.

Furthermore, in the chip transferring and bonding device provided by the present disclosure, by virtue of “the substrate carrying module being configured to be electrically connected to the signal control module,” “the chip transferring module being configured to be electrically connected to the signal control module,” “the chip bonding module being configured to be electrically connected to the signal control module, and the chip bonding module including at least one micro heater,” “the substrate carrying module being allowed to be configured to carry the chip bonding module through the signal control module” and “the chip bonding module being configured to carry a temporary carrying substrate that is configured for carrying a plurality of chips,” when the chip transferring module is optionally configured to be used, the chip transferring module is allowed to be configured to transfer the circuit substrate to the chips that are carried by the temporary carrying substrate through the signal control module, and when the chip bonding module is optionally configured to be used, the at least one micro heater of the chip bonding module is allowed to heat a corresponding one of the chips through the signal control module.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a functional block diagram of a chip transferring and bonding device provided by the present disclosure;

FIG. 2 is a schematic view of the chip transferring and bonding device provided by a first embodiment of the present disclosure (before transferring and bonding a plurality of chips to a circuit substrate);

FIG. 3 is a schematic view of the chip transferring and bonding device provided by the first embodiment of the present disclosure (after transferring and bonding the chips to the circuit substrate through a light source generator);

FIG. 4 is a schematic view of the chip transferring and bonding device configured to remove a temporary carrier substrate according to the first embodiment of the present disclosure;

FIG. 5 is a schematic view of the chip transferring and bonding device provided by the first embodiment of the present disclosure (before debonding two damaged chips);

FIG. 6 is a schematic view of the chip transferring and bonding device provided by the first embodiment of the present disclosure (after debonding the two damaged chips);

FIG. 7 is a schematic view of the chip transferring and bonding device provided by the first embodiment of the present disclosure (before transferring and bonding two new chips to the circuit substrate);

FIG. 8 is a schematic view of the chip transferring and bonding device provided by the first embodiment of the present disclosure (after transferring and bonding the two new chips to the circuit substrate);

FIG. 9 is a schematic view of the chip transferring and bonding device provided by the first embodiment of the present disclosure being configured to remove the temporary carrier substrate again;

FIG. 10 is a schematic view of the chip transferring and bonding device provided by the first embodiment of the present disclosure (after transferring and bonding the chips to the circuit substrate through the heat source generator);

FIG. 11 is a schematic view of the chip transferring and bonding device provided by a second embodiment of the present disclosure (before transferring and bonding a last one of the chips to the circuit substrate);

FIG. 12 is a schematic view of the chip transferring and bonding device provided by the second embodiment of the present disclosure (after transferring and bonding the last one of the chips to the circuit substrate through the heat source generator);

FIG. 13 is a schematic view of the chip transferring and bonding device provided by the second embodiment of the present disclosure (after transferring and bonding the last one of the chips to the circuit substrate through the light source generator);

FIG. 14 is a schematic view of the chip transferring and bonding device configured to remove a chip from a temporary carrier substrate according to a third embodiment of the present disclosure;

FIG. 15 is a schematic view of the chip transferring and bonding device provided by the third embodiment of the present disclosure (after transferring and bonding the last one of the chips to the circuit substrate through the heat source generator);

FIG. 16 is a schematic view of the chip transferring and bonding device provided by the third embodiment of the present disclosure (before debonding the damaged chip);

FIG. 17 is a schematic view of the chip transferring and bonding device provided by the third embodiment of the present disclosure (after debonding the damaged chip);

FIG. 18 is a schematic view of the chip transferring and bonding device provided by the third embodiment of the present disclosure (after transferring and bonding a new chip to the circuit substrate);

FIG. 19 is a schematic view of the chip transferring and bonding device provided by the third embodiment of the present disclosure (after transferring and bonding the last one of the chips to the circuit substrate through the light source generator);

FIG. 20 is a schematic view of the chip transferring and bonding device provided by a fourth embodiment of the present disclosure (before transferring the circuit substrate to the chips); and

FIG. 21 is a schematic view of the chip transferring and bonding device provided by the fourth embodiment of the present disclosure (after transferring the circuit substrate to the chips).

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

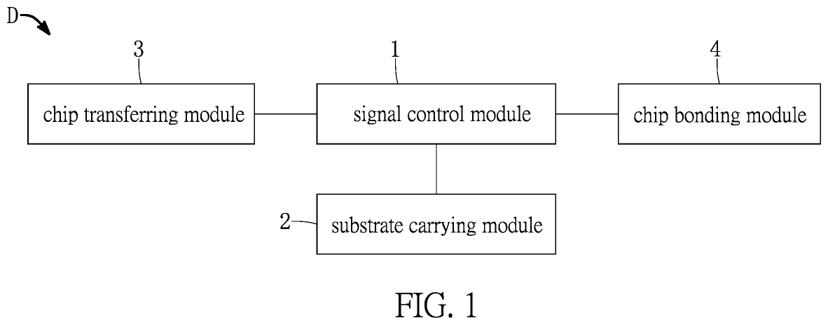

Referring to FIG. 1 to FIG. 21, the present disclosure provides a chip transferring and bonding device D, which includes a signal control module 1, a substrate carrying module 2, a chip transferring module 3 and a chip bonding module 4. More particularly, the substrate carrying module 2 can be configured to be electrically connected to the signal control module 1, the chip transferring module 3 can be configured to be electrically connected to the signal control module 1, and the chip bonding module 4 can be configured to be electrically connected to the signal control module 1. In addition, the chip bonding module 4 includes at least one micro heater or a plurality of micro heaters, and the at least one micro heater or each micro heater of the chip bonding module 4 can be a light source generator 40L that can be configured for generating a light source or a heat source generator 40H that can be configured for generating a heat source. Therefore, when the chip bonding module 4 is optionally configured to be used, the at least one micro heater or each micro heater of the chip bonding module 4 can be allowed to be configured to heat the corresponding one of the chips C through control of the signal control module 1, thereby allowing each of the chips C to be bonded on the circuit substrate P through the at least two corresponding ones of the soldering materials S that have been heated and then cooled (i.e., by heating and then cooling the at least two corresponding ones of the soldering materials S), or thereby allowing the damaged chip BC to be removed from the circuit substrate P through the at least two corresponding ones of the soldering materials S that have been heated (i.e., by heating the at least two corresponding ones of the soldering materials S).

### First Embodiment

Referring to FIG. 1 to FIG. 10, a first embodiment of the present disclosure provides a chip transferring and bonding device D, which includes a signal control module 1, a substrate carrying module 2, a chip transferring module 3 (or a chip moving module, or a chip carrying module) and a chip bonding module 4 (or a chip soldering module). More particularly, the substrate carrying module 2 can be configured to be electrically connected to the signal control module 1, the chip transferring module 3 can be configured to be electrically connected to the signal control module 1, and the chip bonding module 4 can be configured to be electrically connected to the signal control module 1.

For example, referring to FIG. 1 to FIG. 10, the signal control module 1 can be a control unit at least including a CPU, a GPU or any signal control chip, which can be applied to any kind of computer or any kind of portable electronic device. Furthermore, the substrate carrying module 2 can be a movable clamp, a movable vacuum suction nozzle, or any kind of stage, which can be used to carry any kind of substrate. Moreover, the chip transferring module 3 can be a movable clamping jaw, a movable vacuum nozzle, or any kind of chip transferring structure that can be used to transfer the chip from one place to another. In addition, the chip transferring module 3 includes a substrate carrying structure 31 (such as a movable gripper, a movable vacuum nozzle, or any kind of chip transferring structure that can be used to transfer chips from one place to another) configured to carry the temporary carrying substrate T. However, the aforementioned details are disclosed for exemplary purposes only, and are not meant to limit the scope of the present disclosure.

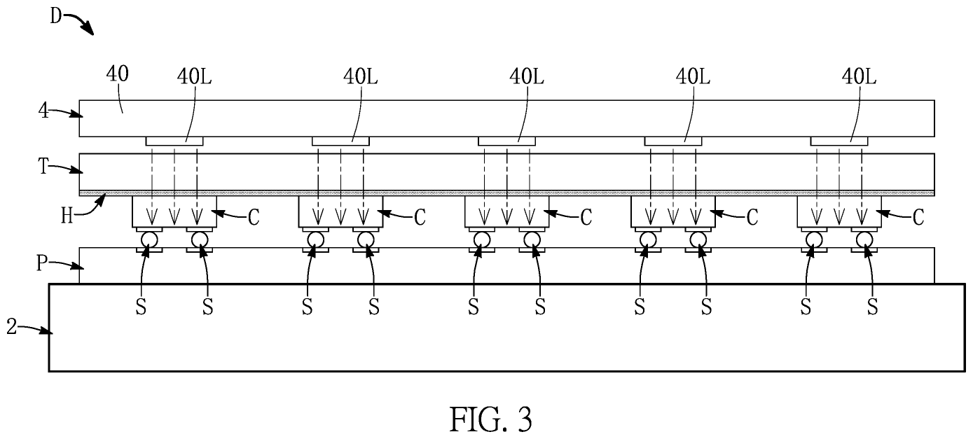

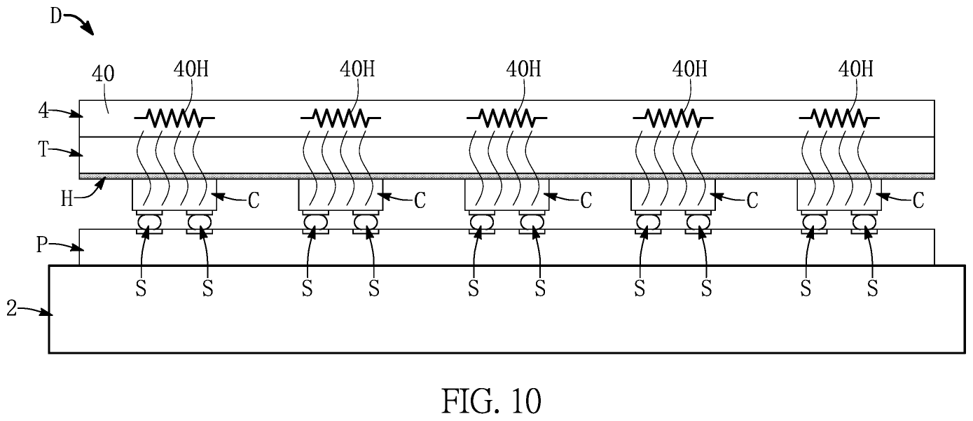

Moreover, referring to FIG. 1 to FIG. 10, the chip bonding module 4 includes at least one micro heater or a plurality of micro heaters. When the chip bonding module 4 includes a plurality of micro heaters, all of the micro heaters are disposed on a carrier substrate 40 of the chip bonding module 4 and respectively correspond to the chips C (such as LED chips or any kind of semiconductor chips, or dies, or electronic components). Moreover, each of the micro heaters of the chip bonding module 4 can be configured as a light source generator 40L (such as a laser diode, a semiconductor chip or any kind of light-emitting chip, which can provide near-field illumination as shown in FIG. 3) that can be configured for generating a light source, or each of the micro heaters of the chip bonding module 4 can be configured as a heat source generator 40H (such as a heating metal wire, a semiconductor chip, or any kind of heating chip as shown in FIG. 10) that can be configured for generating a heat source, and the micro heaters are not disposed inside or outside the temporary carrying substrate T. In addition, the temporary carrying substrate T can be a non-flexible substrate such as a glass substrate, a plastic substrate or a substrate made of any kind of material. It should be noted that when the temporary carrying substrate T can be configured to carry the chips C, the chips C can be adhered to the temporary carrying substrate T through an adhesive layer H, and a predetermined arrangement shape (such as an array shape or a linear shape for providing a predetermined pixel spacing) that is formed by the chips C can correspond to a predetermined arrangement shape (such as an array shape or a linear shape for providing a predetermined pixel spacing) that is formed by the micro heaters. In addition, when the light source generator 40L uses a laser diode (LD), the luminescence wavelength or luminescence waveband provided by the light source generator 40L can be adjusted (without any replacing optical lens) according to different requirements. However, the aforementioned details are disclosed for exemplary purposes only, and are not meant to limit the scope of the present disclosure.

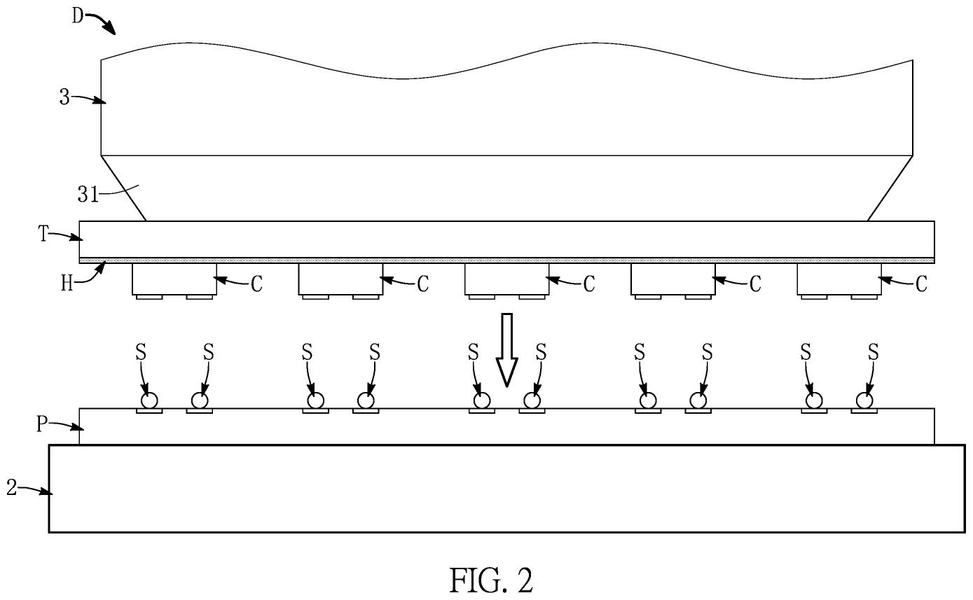

For example, referring to FIG. 1 and FIG. 2, when the substrate carrying module 2 is optionally configured to be used, the substrate carrying module 2 can be allowed to be configured to carry a circuit substrate P (such as any carrier substrate with a circuit layout) through control of the signal control module 1. Moreover, referring to FIG. 1 and FIG. 2, when the chip transferring module 3 is optionally configured to be used, the chip transferring module 3 can be allowed to be configured to carry a temporary carrying substrate T that is configured for carrying a plurality of chips C through control of the signal control module 1. In addition, when the chip transferring module 3 is optionally configured to be used, the chip transferring module 3 can be allowed to be configured to simultaneously transfer the chips C that are carried by the non-flexible substrate (i.e., the temporary carrying substrate T) to the circuit substrate P through vacuum suction of the substrate carrying structure 31 that is controlled by the signal control module 1, thereby allowing each of the chips C to be electrically connected to the circuit substrate P through at least two corresponding ones of a plurality of soldering materials S. However, the aforementioned details are disclosed for exemplary purposes only, and are not meant to limit the scope of the present disclosure.

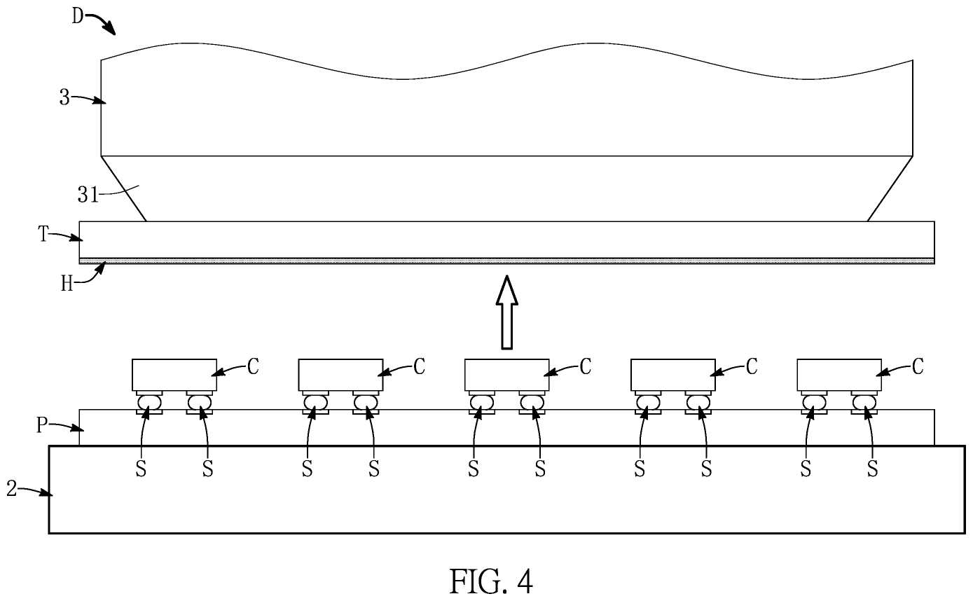

For example, referring to FIG. 1, FIG. 2 and FIG. 3, when the chip transferring module 3 is optionally configured to be used, the chip transferring module 3 can be allowed to be configured to transfer the chips C that are carried by the temporary carrying substrate T to the circuit substrate P through control of the signal control module 1. In addition, referring to FIG. 1, FIG. 3 and FIG. 4, when the chip bonding module 4 is optionally configured to be used, the at least one micro heater (such as multiple light source generators 40L) of the chip bonding module 4 can be allowed to heat a corresponding one of the chips C through control of the signal control module 1. More particularly, referring to FIG. 1, FIG. 3 and FIG. 4, when the chip bonding module 4 is optionally configured to be used, each of the micro heaters (such as each light source generator 40L) of the chip bonding module 4 can be allowed to be configured to optionally heat the corresponding one of the chips C through control of the signal control module 1, thereby simultaneously transmitting a thermal energy generated by all of the micro heaters to all of the chips C (i.e., the micro heaters are all turned on to soldering all of the chips C) or simultaneously transmitting a thermal energy generated by some of the micro heaters to some of the chips C (i.e., the micro heaters are partially turned on to partially soldering some of the chips C). That is to say, referring to FIG. 1, FIG. 3 and FIG. 4, when the chips C are simultaneously transferred to the circuit substrate P through the chip transferring module 3, the chip bonding module 4 can be configured to be disposed above the temporary carrying substrate T, and the micro heaters (such as multiple light source generators 40L) of the chip bonding module 4 are allowed to be configured to respectively heat the chips C through control of the signal control module 1, thereby allowing each of the chips C to be bonded on the circuit substrate P (as shown in FIG. 4) through the at least two corresponding ones of the soldering materials S that have been heated (melted) and then cooled (solidified) (i.e., by heating (melting) and then cooling (solidifying) the at least two corresponding ones of the soldering materials S, that is to say, the micro heater is turned on first for heating and then the micro heater is turned off for cooling). However, the aforementioned details are disclosed for exemplary purposes only, and are not meant to limit the scope of the present disclosure.

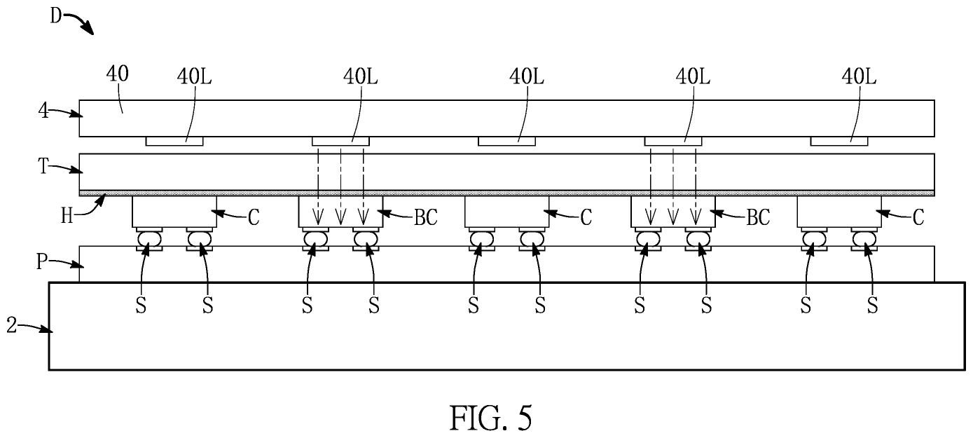

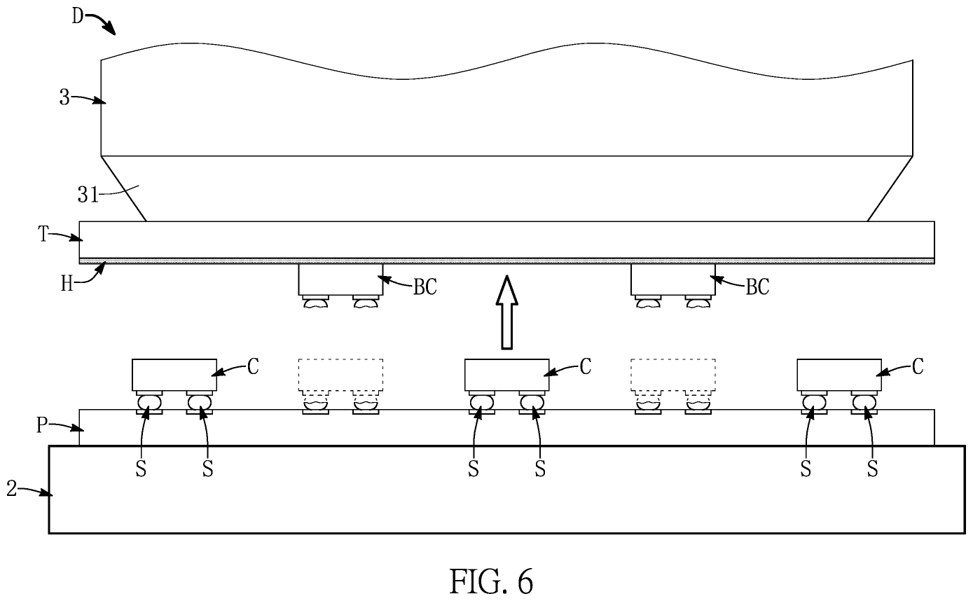

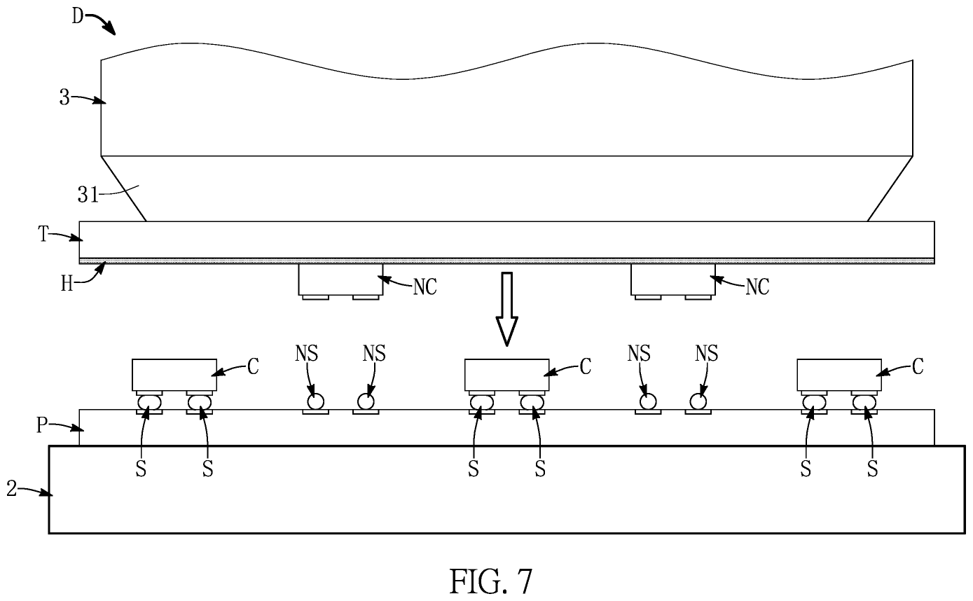

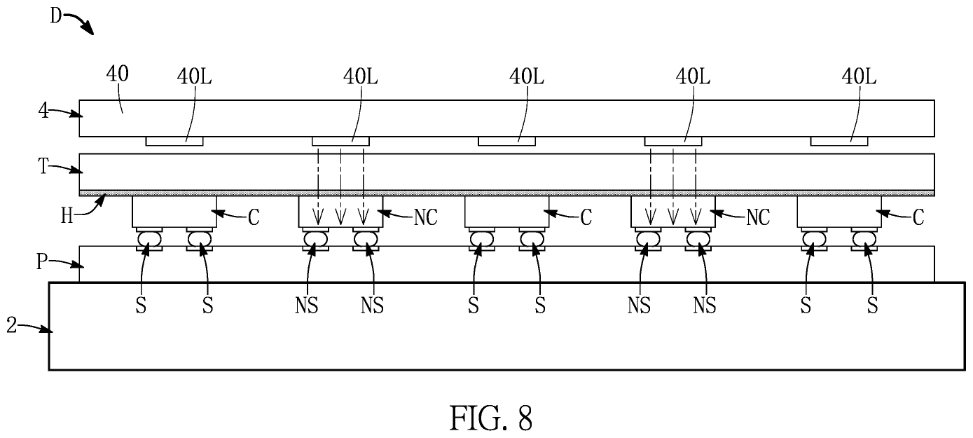

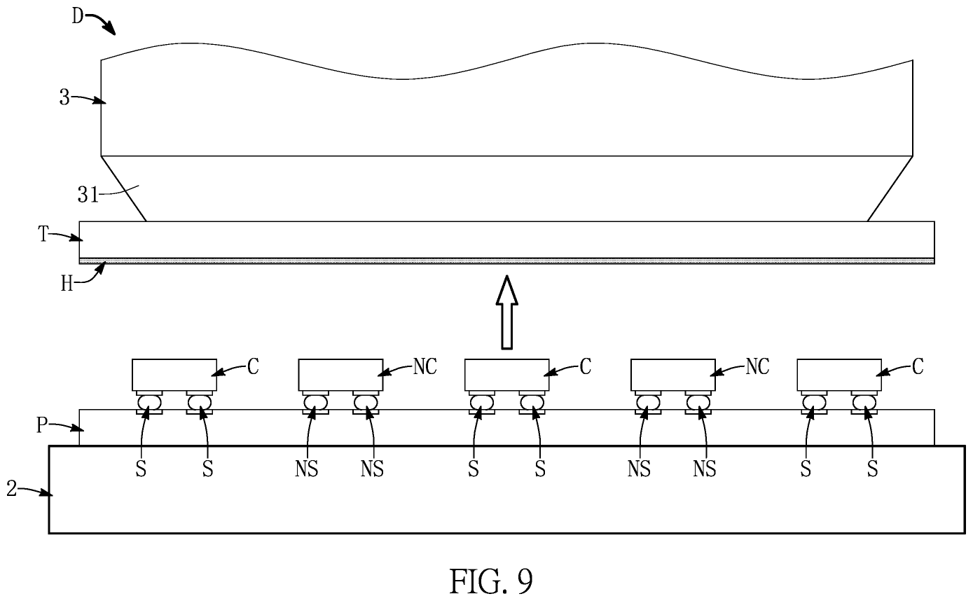

For example, referring to FIG. 1, FIG. 5 and FIG. 6, when one of the chips C bonded on the circuit substrate P is damaged and determined to be a damaged chip BC (e.g., FIG. 5 illustrates “when two chips C bonded on the circuit board P are damaged and determined to be two damaged chips BC” as an example), one of the micro heaters corresponding to the damaged chip BC can be allowed to be configured to heat the damaged chip BC through control of the signal control module 1 (e.g., FIG. 5 illustrates “two micro heaters corresponding to the two damaged chips BC can be configured to heat the two damaged chips BC through the control of the signal control module 1” as an example), thereby allowing the damaged chip BC to be removed from the circuit substrate P through the at least two corresponding ones of the soldering materials S that have been heated (melted) (i.e., by heating (melting) the at least two corresponding ones of the soldering materials S) (e.g., FIG. 6 illustrates “the soldering materials S can be removed and cleaned after the two damaged chips BC are debonded” as an example). In addition, referring to FIG. 1, FIG. 6, FIG. 7, FIG. 8 and FIG. 9, after the damaged chip BC is removed from the circuit substrate P (as shown in FIG. 6), a new chip NC can be transferred to the circuit substrate P through the chip transferring module 3 (i.e., the substrate carrying structure 31) (e.g., FIG. 7 illustrates “two new chips NC can be transferred to the circuit substrate P through the chip transferring module 3” as an example), and at least one of the micro heaters of the chip bonding module 4 can be allowed to be configured to heat the new chip NC through control of the signal control module 1 (e.g., FIG. 8 illustrates “two light source generators 40L of the chip bonding module 4 can be configured to heat the corresponding two new chips NC through the control of the signal control module 1” as an example), thereby allowing the new chip NC to be bonded on the circuit substrate P through a plurality of new soldering materials NS that have been heated (melted) and then cooled (solidified) (i.e., by heating (melting) and then cooling (solidifying) a plurality of new soldering materials NS, that is to say, the micro heater is turned on first for heating and then the micro heater is turned off for cooling) so as to achieve the purpose of chip repair (repairing chip) as shown in FIG. 9. However, the aforementioned details are disclosed for exemplary purposes only, and are not meant to limit the scope of the present disclosure.

Therefore, in the chip transferring and bonding device D provided by the first embodiment of the present disclosure, by virtue of “the substrate carrying module 2 being configured to be electrically connected to the signal control module 1,” “the chip transferring module 3 being configured to be electrically connected to the signal control module 1” and “the chip bonding module 4 being configured to be electrically connected to the signal control module 1, and the chip bonding module 4 including at least one micro heater,” when the chip transferring module 3 is optionally configured to be used, the chip transferring module 3 can be allowed to be configured to transfer the chips C that are carried by the temporary carrying substrate T to the circuit substrate P through control of the signal control module 1, and when the chip bonding module 4 is optionally configured to be used, the at least one micro heater (such as the light source generator 40L or the heat source generator 40H) of the chip bonding module 4 can be allowed to heat a corresponding one of the chips C through control of the signal control module 1.

### Second Embodiment

Referring to FIG. 1 and FIG. 11 to FIG. 13, a second embodiment of the present disclosure provides a chip transferring and bonding device D, which includes a signal control module 1, a substrate carrying module 2, a chip transferring module 3 and a chip bonding module 4. The main difference between the second embodiment and the first embodiment is as follows: in the second embodiment, the chip transferring module 3 includes a push-type pin 32 (or a pushing pin) configured to push against the temporary carrying substrate T and a driving mechanism (not shown) for driving the push-type pin 32.

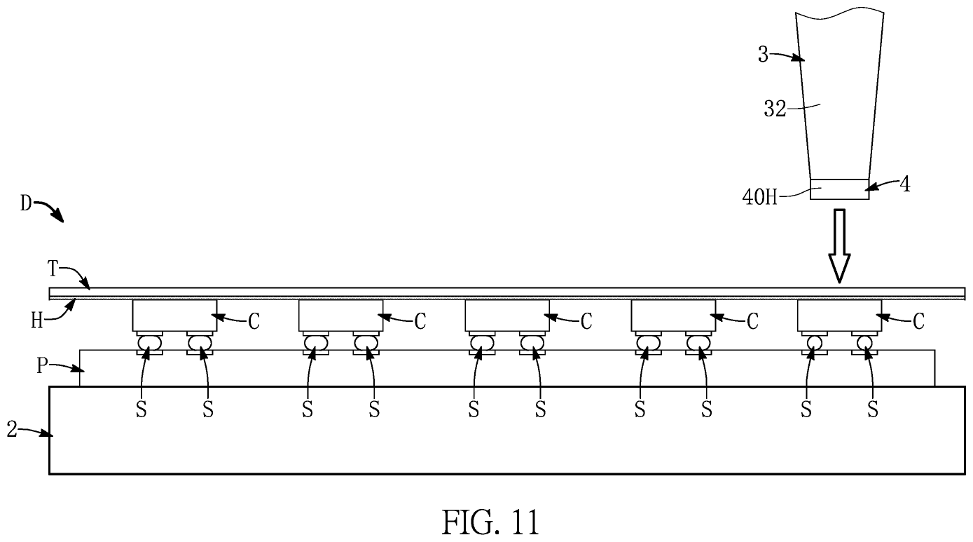

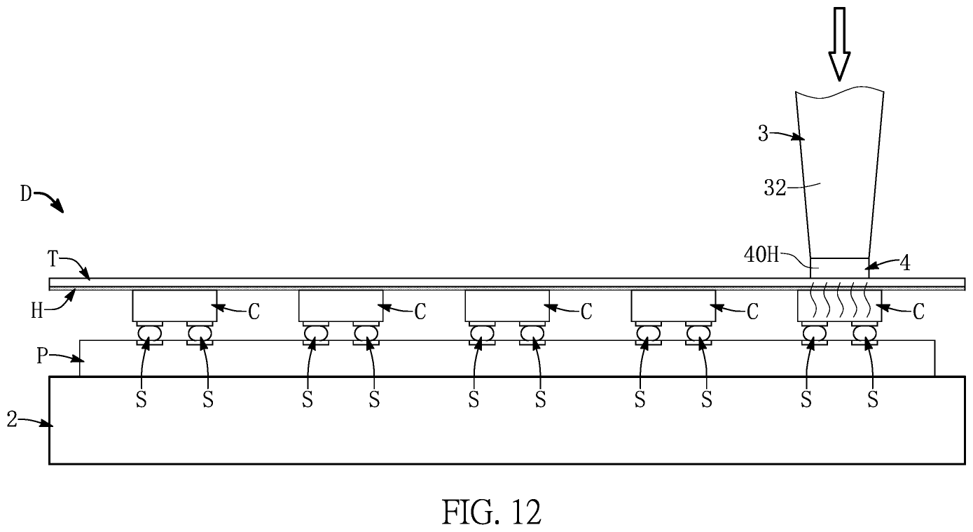

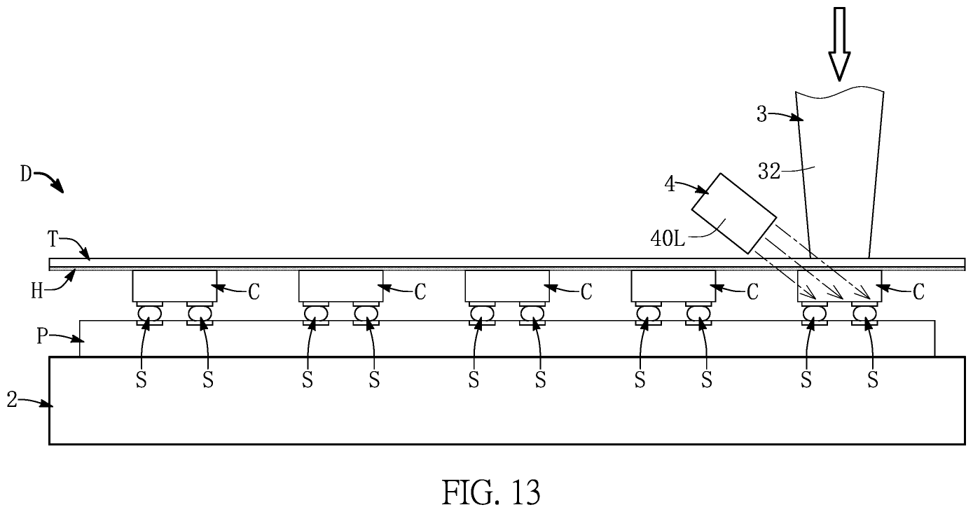

For example, referring to FIG. 1, FIG. 11, FIG. 12 and FIG. 13, the temporary carrying substrate T can be a flexible substrate (such as a blue film or a substrate made of any kind of flexible material). Moreover, the at least one micro heater of the chip bonding module 4 can be configured as a heat source generator 40H (such as a heating metal wire, a semiconductor chip, or any kind of heating chip as shown in FIG. 11) that can be configured for generating a heat source, or the at least one micro heater of the chip bonding module 4 can be configured as a light source generator 40L (such as a laser diode, a semiconductor chip or any kind of light-emitting chip, which can provide near-field illumination as shown in FIG. 13) that can be configured for generating a light source. In addition, the at least one micro heater of the chip bonding module 4 can be configured to be disposed on the push-type pin 32 of the chip transferring module 3 (as shown in FIG. 11, the heat source generator 40H can be disposed on the top of the push-type pin 32) or configured to be adjacent to the push-type pin 32 of the chip transferring module 3 (as shown in FIG. 13, the light source generator 40L can be adjacent to the top of the push-type pin 32). That is to say, as shown in FIG. 13, when the at least one micro heater of the chip bonding module 4 can be configured to be disposed on the push-type pin 32 of the chip transferring module 3, the at least one micro heater of the chip bonding module 4 can be configured as the heat source generator 40H for generating the heat source. In addition, as shown in FIG. 13, when the at least one micro heater of the chip bonding module 4 can be configured to be adjacent to the push-type pin 32 of the chip transferring module 3, the at least one micro heater of the chip bonding module 4 can be configured as the light source generator 40L for generating the light source. It should be noted that the push-type pin 32 may be a unidirectional single-head pin, a unidirectional multi-head pin (having multiple pins extend in the same direction), a bidirectional single-head pin (having two pins extend in two opposite directions), or a bidirectional multi-head type pin. In addition, the push-type pin 32 can also provide an additional vacuum suction function for suctioning the chip C according to different requirements (that is to say, the push-type pin 32 can be a dome needle, a flat pin or a pin with a suction nozzle function). However, the aforementioned details are disclosed for exemplary purposes only, and are not meant to limit the scope of the present disclosure.

For example, referring to FIG. 1 and FIG. 11, when the chip transferring module 3 is optionally configured to be used, the chip transferring module 3 can be allowed to be configured to sequentially transfer the chips C carried by the flexible substrate (i.e., the temporary carrying substrate T) to the circuit substrate P through downward pushing method of the push-type pins 32 that is controlled by the signal control module 1, thereby allowing each of the chips C to be electrically connected to the circuit substrate P through at least two corresponding ones of a plurality of soldering materials S. In addition, referring to FIG. 1, FIG. 12 and FIG. 13, when the chip bonding module 4 is optionally configured to be used, the at least one micro heater (such as the heat source generator 40H or the light source generator 40L) of the chip bonding module 4 can be allowed to be configured to heat a corresponding one of the chips C through control of the signal control module 1, thereby transferring a thermal energy generated by the at least one micro heater (such as the heat source generator 40H or the light source generator 40L) to the corresponding one of the chips C. More particularly, referring to FIG. 1, FIG. 11, FIG. 12 and FIG. 13, when the chips C are sequentially transferred to the circuit substrate P through the chip transferring module 3, the chip bonding module 4 can be allowed to be configured to be disposed above the temporary carrying substrate T, and the at least one micro heater (such as the heat source generator 40H or the light source generator 40L) of the chip bonding module 4 can be allowed to be configured to heat the corresponding one of the chips C through control of the signal control module 1, thereby allowing each of the chips C to be bonded on the circuit substrate P through the at least two corresponding ones of the soldering materials S that have been heated (melted) and then cooled (solidified) (i.e., by heating (melting) and then cooling (solidifying) the at least two corresponding ones of the soldering materials S, that is to say, the micro heater is turned on first for heating and then the micro heater is turned off for cooling). However, the aforementioned details are disclosed for exemplary purposes only, and are not meant to limit the scope of the present disclosure.

Therefore, in the chip transferring and bonding device D provided by the second embodiment of the present disclosure, by virtue of “the substrate carrying module 2 being configured to be electrically connected to the signal control module 1,” “the chip transferring module 3 being configured to be electrically connected to the signal control module 1,” “the chip bonding module 4 being configured to be electrically connected to the signal control module 1, and the chip bonding module 4 including at least one micro heater” and “the at least one micro heater of the chip bonding module 4 being configured as a light source generator 40L configured for generating a light source or a heat source generator 40H configured for generating a heat source,” when the chip transferring module 3 is optionally configured to be used, the chip transferring module 3 can be allowed to be configured to transfer the chips C that are carried by the temporary carrying substrate T to the circuit substrate P through control of the signal control module 1, and when the chip bonding module 4 is optionally configured to be used, the at least one micro heater (such as the heat source generator 40H or the light source generator 40L) of the chip bonding module 4 can be allowed to heat a corresponding one of the chips C through control of the signal control module 1.

### Third Embodiment

Referring to FIG. 1 and FIG. 14 to FIG. 19, a third embodiment of the present disclosure provides a chip transferring and bonding device D, which includes a signal control module 1, a substrate carrying module 2, a chip transferring module 3 and a chip bonding module 4. The main difference between the third embodiment and the first embodiment is as follows: in the third embodiment, the chip transferring module 3 includes a chip suction nozzle 33 configured to suction or suck the chip C and a driving mechanism (not shown) for driving the chip suction nozzle 33.

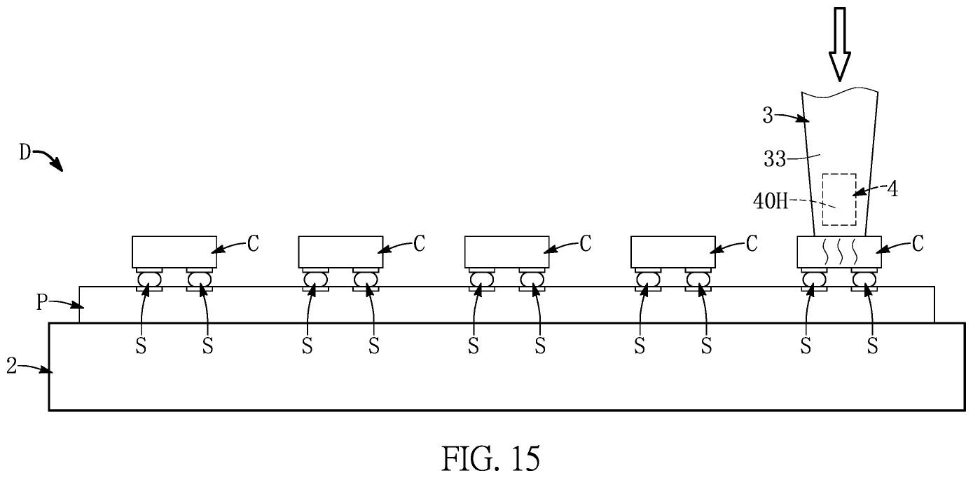

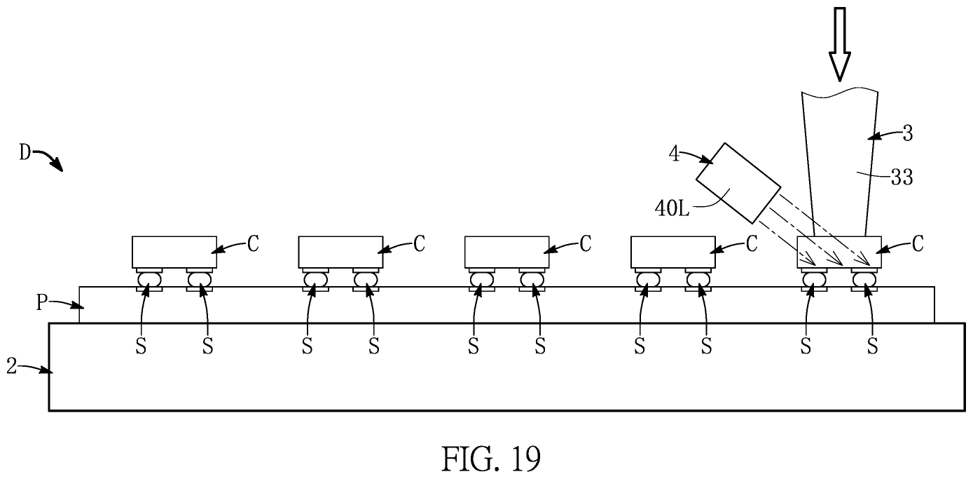

For example, referring to FIG. 1, FIG. 11, FIG. 12 and FIG. 13, the temporary carrying substrate T can be a non-flexible substrate (such as a glass substrate, a plastic substrate or a substrate made of any kind of material) or a flexible substrate (such as a blue film or a substrate made of any kind of flexible material). Moreover, the at least one micro heater of the chip bonding module 4 can be configured as a heat source generator 40H (such as a heating metal wire, a semiconductor chip, or any kind of heating chip as shown in FIG. 15) that can be configured for generating a heat source, or the at least one micro heater of the chip bonding module 4 can be configured as a light source generator 40L (such as a laser diode, a semiconductor chip or any kind of light-emitting chip, which can provide near-field illumination as shown in FIG. 19) that can be configured for generating a light source. In addition, the at least one micro heater of the chip bonding module 4 can be configured to be disposed on the chip suction nozzle 33 of the chip transferring module 3 (as shown in FIG. 15, the heat source generator 40H can be disposed inside or outside the top of the chip suction nozzle 33) or configured to be adjacent to the chip suction nozzle 33 of the chip transferring module 3 (as shown in FIG. 19, the light source generator 40L can be adjacent to the top of the chip suction nozzle 33). That is to say, as shown in FIG. 15, when the at least one micro heater of the chip bonding module 4 can be configured to be disposed on the chip suction nozzle 33 of the chip transferring module 3, the at least one micro heater of the chip bonding module 4 can be configured as the heat source generator 40H for generating the heat source. As shown in FIG. 19, when the at least one micro heater of the chip bonding module 4 can be configured to be adjacent to the chip suction nozzle 33 of the chip transferring module 3, the at least one micro heater of the chip bonding module 4 can be configured as the light source generator 40L for generating the light source. In addition, the chip suction nozzle 33 can also provide an additional push function to push the chip C (such as the push-type pin 32 provided in the second embodiment) according to different requirements. However, the aforementioned details are disclosed for exemplary purposes only, and are not meant to limit the scope of the present disclosure.

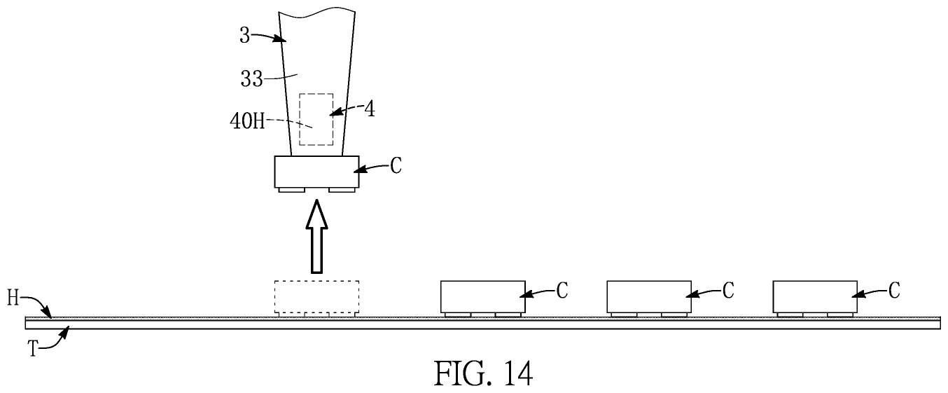

For example, referring to FIG. 1, FIG. 14 and FIG. 15, when the chip transferring module 3 is optionally configured to be used, the chip transferring module 3 can be allowed to be configured to sequentially transfer the chips C carried by the non-flexible substrate or the flexible substrate (i.e., the temporary carrying substrate T) to the circuit substrate P through vacuum suction of the chip suction nozzle 33 controlled by the signal control module 1, thereby allowing each of the chips C to be electrically connected to the circuit substrate P through at least two corresponding ones of a plurality of soldering materials S. In addition, referring to FIG. 1, FIG. 15 and FIG. 19, when the chip bonding module 4 is optionally configured to be used, the at least one micro heater (such as the heat source generator 40H or the light source generator 40L) of the chip bonding module 4 can be allowed to be configured to heat a corresponding one of the chips C through control of the signal control module 1, thereby transferring a thermal energy generated by the at least one micro heater (such as the heat source generator 40H or the light source generator 40L) to the corresponding one of the chips C. More particularly, referring to FIG. 1, FIG. 14, FIG. 15 and FIG. 19, when the chips C are sequentially transferred to the circuit substrate P through the chip transferring module 3, the at least one micro heater (such as the heat source generator 40H or the light source generator 40L) of the chip bonding module 4 can be allowed to be configured to heat the corresponding one of the chips C through control of the signal control module 1, thereby allowing each of the chips C to be bonded on the circuit substrate P through the at least two corresponding ones of the soldering materials S that have been heated (melted) and then cooled (solidified) (i.e., by heating (melting) and then cooling (solidifying) the at least two corresponding ones of the soldering materials S, that is to say, the micro heater is turned on first for heating and then the micro heater is turned off for cooling). However, the aforementioned details are disclosed for exemplary purposes only, and are not meant to limit the scope of the present disclosure.

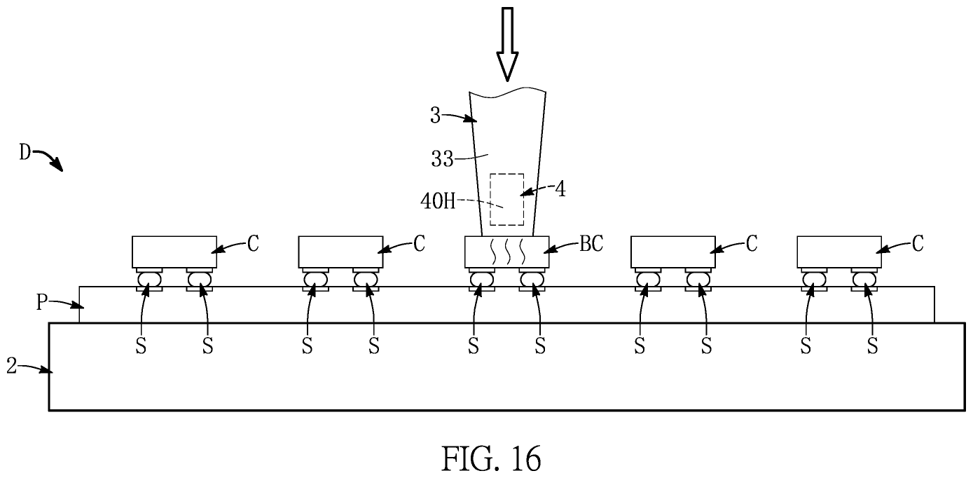

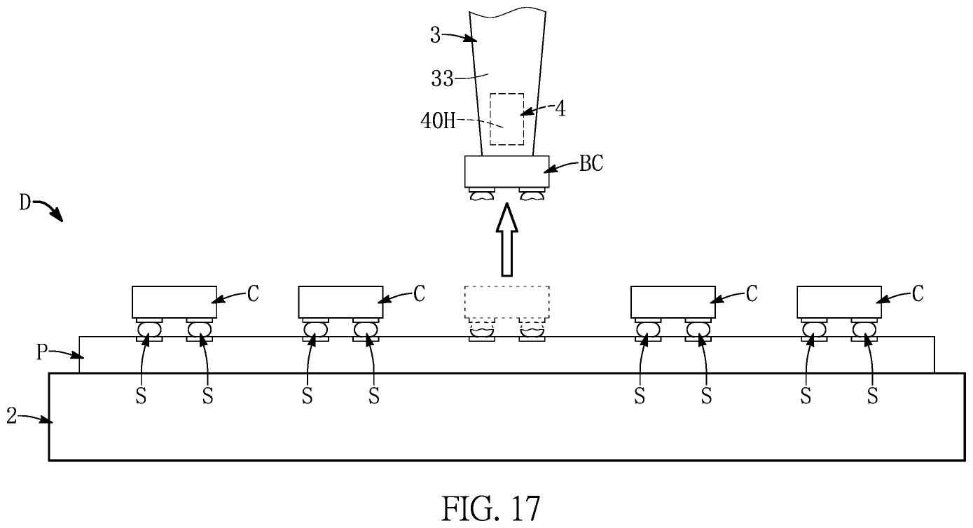

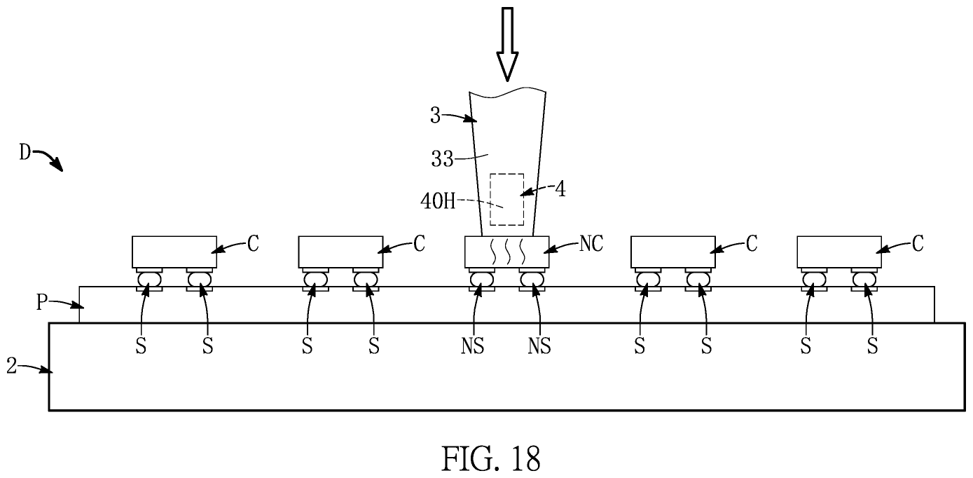

For example, referring to FIG. 1, FIG. 16 and FIG. 17, when one of the chips C bonded on the circuit substrate P is damaged and determined to be a damaged chip BC, the at least one micro heater corresponding to the damaged chip BC can be allowed to be configured to heat the damaged chip BC through control of the signal control module 1, thereby allowing the damaged chip BC to be removed from the circuit substrate P through the at least two corresponding ones of the soldering materials S that have been heated (melted) (i.e., by heating (melting) the at least two corresponding ones of the soldering materials S) (e.g., FIG. 6 illustrates “the soldering materials S can be removed and cleaned after the two damaged chips BC are debonded” as an example). In addition, referring to FIG. 1, FIG. 17 and FIG. 18, after the damaged chip BC is removed from the circuit substrate P (as shown in FIG. 17), a new chip NC can be transferred to the circuit substrate P through the chip transferring module 3 (i.e., the chip suction nozzle 33), and the at least one micro heater (such as the heat source generator 40H) of the chip bonding module 4 can be allowed to be configured to heat the new chip NC through control of the signal control module 1, thereby allowing the new chip NC to be bonded on the circuit substrate P through a plurality of new soldering materials NS that have been heated (melted) and then cooled (solidified) (i.e., by heating (melting) and then cooling (solidifying) a plurality of new soldering materials NS, that is to say, the micro heater is turned on first for heating and then the micro heater is turned off for cooling) so as to achieve the purpose of chip repair (repairing chip) as shown in FIG. 18. However, the aforementioned details are disclosed for exemplary purposes only, and are not meant to limit the scope of the present disclosure.

Therefore, in the chip transferring and bonding device D provided by the third embodiment of the present disclosure, by virtue of “the substrate carrying module 2 being configured to be electrically connected to the signal control module 1,” “the chip transferring module 3 being configured to be electrically connected to the signal control module 1,” “the chip bonding module 4 being configured to be electrically connected to the signal control module 1, and the chip bonding module 4 including at least one micro heater” and “the at least one micro heater of the chip bonding module 4 being configured as a light source generator 40L configured for generating a light source or a heat source generator 40H configured for generating a heat source,” when the chip transferring module 3 is optionally configured to be used, the chip transferring module 3 can be allowed to be configured to transfer the chips C that are carried by the temporary carrying substrate T to the circuit substrate P through control of the signal control module 1, and when the chip bonding module 4 is optionally configured to be used, the at least one micro heater (such as the heat source generator 40H or the light source generator 40L) of the chip bonding module 4 can be allowed to heat a corresponding one of the chips C through control of the signal control module 1.

### Fourth Embodiment

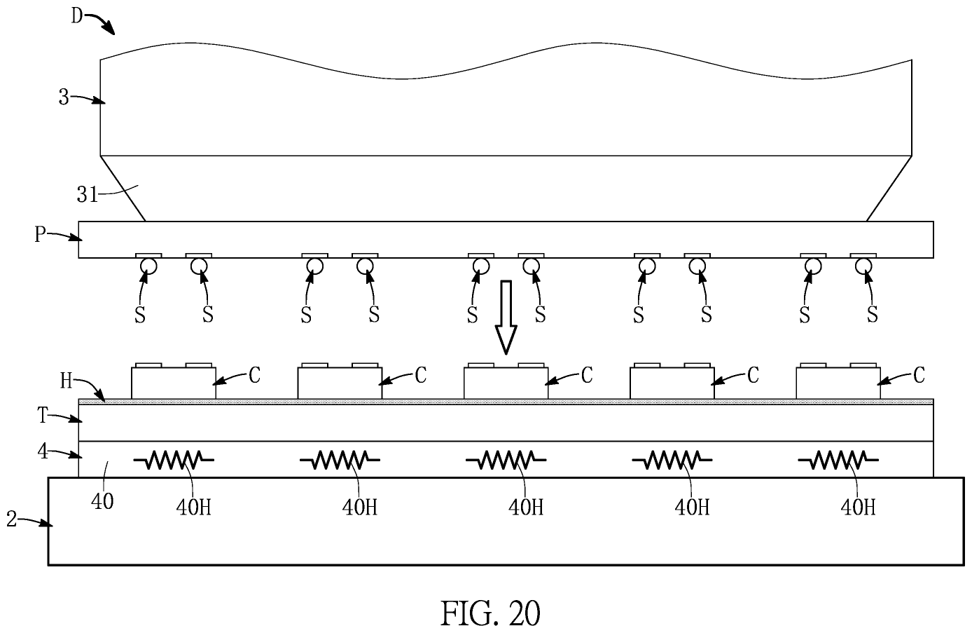

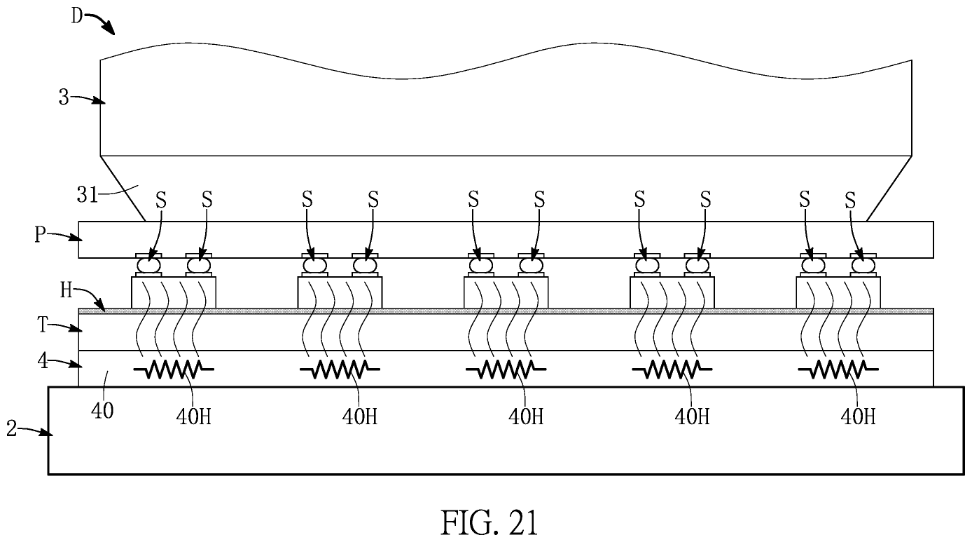

Referring to FIG. 1, FIG. 20 and FIG. 21, a fourth embodiment of the present disclosure provides a chip transferring and bonding device D, which includes a signal control module 1, a substrate carrying module 2, a chip transferring module 3 and a chip bonding module 4. Comparing FIG. 20 with FIG. 2, and comparing FIG. 21 with FIG. 3, the main difference between the fourth embodiment and the first embodiment is as follows: in the fourth embodiment, each of the micro heaters of the chip bonding module 4 can be configured as a heat source generator 40H that can be configured for generating a heat source.

For example, referring to FIG. 1 and FIG. 20, when the substrate carrying module 2 is optionally configured to be used, the substrate carrying module 2 can be allowed to be configured to carry the chip bonding module 4 (including the heat source generator 40H) through control of the signal control module 1. In addition, referring to FIG. 1 and FIG. 20, when the chip bonding module 4 (including the heat source generator 40H) is optionally configured to be used, the chip bonding module 4 can be configured to carry a temporary carrying substrate T that is configured for carrying a plurality of chips C. However, the aforementioned details are disclosed for exemplary purposes only, and are not meant to limit the scope of the present disclosure.

For example, referring to FIG. 1 and FIG. 20, when the chip transferring module 3 is optionally configured to be used, the chip transferring module 3 can be allowed to be configured to carry a circuit substrate P through control of the signal control module 1. In addition, referring to FIG. 1, FIG. 20 and FIG. 21, when the chip transferring module 3 is optionally configured to be used, the chip transferring module 3 can be allowed to be configured to transfer the circuit substrate P to the chips C that are carried by the temporary carrying substrate T through control of the signal control module 1. More particularly, referring to FIG. 1, FIG. 20 and FIG. 21, when the chip transferring module 3 is optionally configured to be used, the chip transferring module 3 can be allowed to be configured to transfer the circuit substrate P to the chips C through control of the signal control module 1, thereby allowing each of the chips C to be electrically connected to the circuit substrate P through at least two corresponding ones of a plurality of soldering materials S. However, the aforementioned details are disclosed for exemplary purposes only, and are not meant to limit the scope of the present disclosure.

For example, referring to FIG. 1 and FIG. 21, when the chip bonding module 4 is optionally configured to be used, the at least one micro heater (such as the heat source generator 40H) of the chip bonding module 4 can be allowed to heat a corresponding one of the chips C through control of the signal control module 1. More particularly, referring to FIG. 1 and FIG. 21, when the chip bonding module 4 is optionally configured to be used, each of the micro heaters (such as multiple heat source generators 40H) of the chip bonding module 4 can be allowed to be configured to optionally heat the corresponding one of the chips C through control of the signal control module 1, thereby simultaneously transmitting a thermal energy generated by all of the micro heaters to all of the chips C or simultaneously transmitting a thermal energy generated by some of the micro heaters to some of the chips C. That is to say, referring to FIG. 1, FIG. 20 and FIG. 21, when the circuit substrate P is transferred to the chips C through the chip transferring module 3, the chip bonding module 4 can be configured to be disposed under the temporary carrying substrate T, and the micro heaters (such as multiple heat source generators 40H) of the chip bonding module 4 are allowed to be configured to respectively heat the chips C through control of the signal control module 1, thereby allowing each of the chips C to be bonded on the circuit substrate P through the at least two corresponding ones of the soldering materials S that have been heated (melted) and then cooled (solidified) (i.e., by heating (melting) and then cooling (solidifying) the at least two corresponding ones of the soldering materials S, that is to say, the micro heater is turned on first for heating and then the micro heater is turned off for cooling). However, the aforementioned details are disclosed for exemplary purposes only, and are not meant to limit the scope of the present disclosure.

Therefore, in the chip transferring and bonding device D provided by the fourth embodiment of the present disclosure, by virtue of “the substrate carrying module 2 being configured to be electrically connected to the signal control module 1,” “the chip transferring module 3 being configured to be electrically connected to the signal control module 1,” “the chip bonding module 4 being configured to be electrically connected to the signal control module 1, and the chip bonding module 4 including at least one micro heater,” “the substrate carrying module 2 being allowed to be configured to carry the chip bonding module 4 through control of the signal control module 1” and “the chip bonding module 4 being configured to carry a temporary carrying substrate T that is configured for carrying a plurality of chips C,” when the chip transferring module 3 is optionally configured to be used, the chip transferring module 3 can be allowed to be configured to transfer the circuit substrate P to the chips C that are carried by the temporary carrying substrate T through control of the signal control module 1, and when the chip bonding module 4 is optionally configured to be used, the at least one micro heater (such as the heat source generators 40H) of the chip bonding module 4 can be allowed to heat a corresponding one of the chips C through control of the signal control module 1.

### Beneficial Effects of the Embodiments

In conclusion, in the chip transferring and bonding device D provided by the present disclosure, by virtue of “the substrate carrying module 2 being configured to be electrically connected to the signal control module 1,” “the chip transferring module 3 being configured to be electrically connected to the signal control module 1” and “the chip bonding module 4 being configured to be electrically connected to the signal control module 1, and the chip bonding module 4 including at least one micro heater,” when the chip transferring module 3 is optionally configured to be used, the chip transferring module 3 can be allowed to be configured to transfer the chips C that are carried by the temporary carrying substrate T to the circuit substrate P through control of the signal control module 1, and when the chip bonding module 4 is optionally configured to be used, the at least one micro heater of the chip bonding module 4 can be allowed to heat a corresponding one of the chips C through control of the signal control module 1.

Furthermore, in the chip transferring and bonding device D provided by the present disclosure, by virtue of “the substrate carrying module 2 being configured to be electrically connected to the signal control module 1,” “the chip transferring module 3 being configured to be electrically connected to the signal control module 1,” “the chip bonding module 4 being configured to be electrically connected to the signal control module 1, and the chip bonding module 4 including at least one micro heater” and “the at least one micro heater of the chip bonding module 4 being configured as a light source generator 40L configured for generating a light source or a heat source generator 40H configured for generating a heat source,” when the chip transferring module 3 is optionally configured to be used, the chip transferring module 3 can be allowed to be configured to transfer the chips C that are carried by the temporary carrying substrate T to the circuit substrate P through control of the signal control module 1, and when the chip bonding module 4 is optionally configured to be used, the at least one micro heater of the chip bonding module 4 can be allowed to heat a corresponding one of the chips C through control of the signal control module 1.

Furthermore, in the chip transferring and bonding device D provided by the present disclosure, by virtue of “the substrate carrying module 2 being configured to be electrically connected to the signal control module 1,” “the chip transferring module 3 being configured to be electrically connected to the signal control module 1,” “the chip bonding module 4 being configured to be electrically connected to the signal control module 1, and the chip bonding module 4 including at least one micro heater” and “the substrate carrying module 2 being configured to be electrically connected to the signal control module 1,” “the chip transferring module 3 being configured to be electrically connected to the signal control module 1,” “the substrate carrying module 2 being allowed to be configured to carry the chip bonding module 4 through control of the signal control module 1” and “the chip bonding module 4 being configured to carry a temporary carrying substrate T that is configured for carrying a plurality of chips C,” when the chip transferring module 3 is optionally configured to be used, the chip transferring module 3 can be allowed to be configured to transfer the circuit substrate P to the chips C that are carried by the temporary carrying substrate T through control of the signal control module 1, and when the chip bonding module 4 is optionally configured to be used, the at least one micro heater of the chip bonding module 4 can be allowed to heat a corresponding one of the chips C through control of the signal control module 1.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A chip transferring and bonding device, comprising:
a signal control module;
a substrate carrying module configured to be electrically connected to the signal control module;
a chip transferring module configured to be electrically connected to the signal control module; and
a chip bonding module configured to be electrically connected to the signal control module, wherein the chip bonding module includes at least one micro heater;
wherein, when the substrate carrying module is optionally configured to be used, the substrate carrying module is allowed to be configured to carry a circuit substrate through the signal control module;
wherein, when the chip transferring module is optionally configured to be used, the chip transferring module is allowed to be configured to carry a temporary carrying substrate that is configured for carrying a plurality of chips through the signal control module;
wherein, when the chip transferring module is optionally configured to be used, the chip transferring module is allowed to be configured to transfer the chips that are carried by the temporary carrying substrate to the circuit substrate through the signal control module;
wherein, when the chip bonding module is optionally configured to be used, the at least one micro heater of the chip bonding module is allowed to heat a corresponding one of the chips through the signal control module.

2. The chip transferring and bonding device according to claim 1,
wherein, when the chip bonding module includes a plurality of micro heaters, the micro heaters are disposed on a carrier substrate of the chip bonding module and respectively correspond to the chips, and the micro heaters are not disposed inside or outside the temporary carrying substrate;
wherein the chip transferring module includes a substrate carrying structure configured to carry the temporary carrying substrate, the temporary carrying substrate is a non-flexible substrate, and each of the micro heaters of the chip bonding module is a light source generator configured for generating a light source or a heat source generator configured for generating a heat source;
wherein, when the chip transferring module is optionally configured to be used, the chip transferring module is allowed to be configured to simultaneously transfer the chips that are carried by the non-flexible substrate to the circuit substrate through the substrate carrying structure controlled by the signal control module, thereby allowing each of the chips to be electrically connected to the circuit substrate through at least two corresponding ones of a plurality of soldering materials;
wherein, when the chip bonding module is optionally configured to be used, each of the micro heaters of the chip bonding module is allowed to be configured to optionally heat the corresponding one of the chips through the signal control module, thereby simultaneously transmitting a thermal energy generated by all of the micro heaters to all of the chips or simultaneously transmitting a thermal energy generated by some of the micro heaters to some of the chips;
wherein, when the chips are simultaneously transferred to the circuit substrate through the chip transferring module, the chip bonding module is configured to be disposed above the temporary carrying substrate, and the micro heaters of the chip bonding module are allowed to be configured to respectively heat the chips through the signal control module, thereby allowing each of the chips to be bonded on the circuit substrate through the at least two corresponding ones of the soldering materials that have been heated and then cooled;
wherein, when one of the chips bonded on the circuit substrate is damaged and determined to be a damaged chip, one of the micro heaters corresponding to the damaged chip is allowed to be configured to heat the damaged chip through the signal control module, thereby allowing the damaged chip to be removed from the circuit substrate through the at least two corresponding ones of the soldering materials that have been heated;
wherein, after the damaged chip is removed from the circuit substrate, a new chip is transferred to the circuit substrate through the chip transferring module, and one of the micro heaters of the chip bonding module is allowed to be configured to heat the new chip through the signal control module, thereby allowing the new chip to be bonded on the circuit substrate through a plurality of new soldering materials that have been heated and then cooled;
wherein, when the temporary carrying substrate is configured to carry the chips, the chips are adhered to the temporary carrying substrate through an adhesive layer, and a predetermined arrangement shape formed by the chips corresponds to a predetermined arrangement shape formed by the micro heaters.

3. The chip transferring and bonding device according to claim 1,
wherein the at least one micro heater is not be disposed inside or outside the temporary carrying substrate;
wherein the chip transferring module includes a push-type pin configured to push against the temporary carrying substrate, the temporary carrying substrate is a flexible substrate, and the at least one micro heater of the chip bonding module is a light source generator configured for generating a light source or a heat source generator configured for generating a heat source;
wherein the at least one micro heater of the chip bonding module is configured to be disposed on the push-type pin of the chip transferring module or configured to be adjacent to the push-type pin of the chip transferring module;
wherein, when the at least one micro heater of the chip bonding module is configured to be disposed on the push-type pin of the chip transferring module, the at least one micro heater of the chip bonding module is configured as the heat source generator for generating the heat source;
wherein, when the at least one micro heater of the chip bonding module is configured to be adjacent to the push-type pin of the chip transferring module, the at least one micro heater of the chip bonding module is configured as the light source generator for generating the light source;
wherein, when the chip transferring module is optionally configured to be used, the chip transferring module is allowed to be configured to sequentially transfer the chips carried by the flexible substrate to the circuit substrate through the push-type pins controlled by the signal control module, thereby allowing each of the chips to be electrically connected to the circuit substrate through at least two corresponding ones of a plurality of soldering materials;
wherein, when the chip bonding module is optionally configured to be used, the at least one micro heater of the chip bonding module is allowed to be configured to heat a corresponding one of the chips through the signal control module, thereby transferring a thermal energy generated by the at least one micro heater to the corresponding one of the chips;
wherein, when the chips are sequentially transferred to the circuit substrate through the chip transferring module, the chip bonding module is allowed to be configured to be disposed above the temporary carrying substrate, and the at least one micro heater of the chip bonding module is allowed to be configured to heat the corresponding one of the chips through the signal control module, thereby allowing each of the chips to be bonded on the circuit substrate through the at least two corresponding ones of the soldering materials that have been heated and then cooled;
wherein, when the temporary carrying substrate is configured to carry the chips, the chips are adhered to the temporary carrying substrate through an adhesive layer.

4. The chip transferring and bonding device according to claim 1,
wherein the at least one micro heater is not be disposed inside or outside the temporary carrying substrate;
wherein the chip transferring module includes a chip suction nozzle configured to suction the chip, the temporary carrying substrate is a non-flexible substrate or a flexible substrate, and the at least one micro heater of the chip bonding module is a light source generator configured for generating a light source or a heat source generator configured for generating a heat source;
wherein the at least one micro heater of the chip bonding module is configured to be disposed on the chip suction nozzle of the chip transferring module or configured to be adjacent to the chip suction nozzle of the chip transferring module;
wherein, when the at least one micro heater of the chip bonding module is configured to be disposed on the chip suction nozzle of the chip transferring module, the at least one micro heater of the chip bonding module is configured as the heat source generator for generating the heat source;
wherein, when the at least one micro heater of the chip bonding module is configured to be adjacent to the chip suction nozzle of the chip transferring module, the at least one micro heater of the chip bonding module is configured as the light source generator for generating the light source;
wherein, when the chip transferring module is optionally configured to be used, the chip transferring module is allowed to be configured to sequentially transfer the chips carried by the non-flexible substrate or the flexible substrate to the circuit substrate through the chip suction nozzle controlled by the signal control module, thereby allowing each of the chips to be electrically connected to the circuit substrate through at least two corresponding ones of a plurality of soldering materials;
wherein, when the chip bonding module is optionally configured to be used, the at least one micro heater of the chip bonding module is allowed to be configured to heat a corresponding one of the chips through the signal control module, thereby transferring a thermal energy generated by the at least one micro heater to the corresponding one of the chips;
wherein, when the chips are sequentially transferred to the circuit substrate through the chip transferring module, the at least one micro heater of the chip bonding module is allowed to be configured to heat the corresponding one of the chips through the signal control module, thereby allowing each of the chips to be bonded on the circuit substrate through the at least two corresponding ones of the soldering materials that have been heated and then cooled;
wherein, when one of the chips bonded on the circuit substrate is damaged and determined to be a damaged chip, the at least one micro heater corresponding to the damaged chip is allowed to be configured to heat the damaged chip through the signal control module, thereby allowing the damaged chip to be removed from the circuit substrate through the at least two corresponding ones of the soldering materials that have been heated;
wherein, after the damaged chip is removed from the circuit substrate, a new chip is transferred to the circuit substrate through the chip transferring module, and the at least one micro heater of the chip bonding module is allowed to be configured to heat the new chip through the signal control module, thereby allowing the new chip to be bonded on the circuit substrate through a plurality of new soldering materials that have been heated and then cooled;
wherein, when the temporary carrying substrate is configured to carry the chips, the chips are adhered to the temporary carrying substrate through an adhesive layer.

5. A chip transferring and bonding device, comprising:
a signal control module;
a substrate carrying module configured to be electrically connected to the signal control module;
a chip transferring module configured to be electrically connected to the signal control module; and
a chip bonding module configured to be electrically connected to the signal control module;
wherein the chip bonding module includes at least one micro heater, and the at least one micro heater of the chip bonding module is a light source generator configured for generating a light source or a heat source generator configured for generating a heat source.

6. The chip transferring and bonding device according to claim 5,
wherein, when the substrate carrying module is optionally configured to be used, the substrate carrying module is allowed to be configured to carry a circuit substrate through the signal control module;
wherein, when the chip transferring module is optionally configured to be used, the chip transferring module is allowed to be configured to carry a temporary carrying substrate that is configured for carrying a plurality of chips through the signal control module;
wherein, when the chip bonding module includes a plurality of micro heaters, the micro heaters are disposed on a carrier substrate of the chip bonding module and respectively correspond to the chips, and the micro heaters are not disposed inside or outside the temporary carrying substrate;
wherein the chip transferring module includes a substrate carrying structure configured to carry the temporary carrying substrate, the temporary carrying substrate is a non-flexible substrate, and each of the micro heaters of the chip bonding module is a light source generator configured for generating a light source or a heat source generator configured for generating a heat source;
wherein, when the chip transferring module is optionally configured to be used, the chip transferring module is allowed to be configured to simultaneously transfer the chips that are carried by the non-flexible substrate to the circuit substrate through the substrate carrying structure controlled by the signal control module, thereby allowing each of the chips to be electrically connected to the circuit substrate through at least two corresponding ones of a plurality of soldering materials;
wherein, when the chip bonding module is optionally configured to be used, each of the micro heaters of the chip bonding module is allowed to be configured to optionally heat the corresponding one of the chips through the signal control module, thereby simultaneously transmitting a thermal energy generated by all of the micro heaters to all of the chips or simultaneously transmitting a thermal energy generated by some of the micro heaters to some of the chips;
wherein, when the chips are simultaneously transferred to the circuit substrate through the chip transferring module, the chip bonding module is configured to be disposed above the temporary carrying substrate, and the micro heaters of the chip bonding module are allowed to be configured to respectively heat the chips through the signal control module, thereby allowing each of the chips to be bonded on the circuit substrate through the at least two corresponding ones of the soldering materials that have been heated and then cooled;
wherein, when one of the chips bonded on the circuit substrate is damaged and determined to be a damaged chip, one of the micro heaters corresponding to the damaged chip is allowed to be configured to heat the damaged chip through the signal control module, thereby allowing the damaged chip to be removed from the circuit substrate through the at least two corresponding ones of the soldering materials that have been heated;
wherein, after the damaged chip is removed from the circuit substrate, a new chip is transferred to the circuit substrate through the chip transferring module, and one of the micro heaters of the chip bonding module is allowed to be configured to heat the new chip through the signal control module, thereby allowing the new chip to be bonded on the circuit substrate through a plurality of new soldering materials that have been heated and then cooled;
wherein, when the temporary carrying substrate is configured to carry the chips, the chips are adhered to the temporary carrying substrate through an adhesive layer, and a predetermined arrangement shape formed by the chips corresponds to a predetermined arrangement shape formed by the micro heaters.

7. The chip transferring and bonding device according to claim 5,
wherein, when the substrate carrying module is optionally configured to be used, the substrate carrying module is allowed to be configured to carry a circuit substrate through the signal control module;
wherein, when the chip transferring module is optionally configured to be used, the chip transferring module is allowed to be configured to carry a temporary carrying substrate that is configured for carrying a plurality of chips through the signal control module;
wherein the at least one micro heater is not be disposed inside or outside the temporary carrying substrate;
wherein the chip transferring module includes a push-type pin configured to push against the temporary carrying substrate, and the temporary carrying substrate is a flexible substrate;
wherein the at least one micro heater of the chip bonding module is configured to be disposed on the push-type pin of the chip transferring module or configured to be adjacent to the push-type pin of the chip transferring module;
wherein, when the at least one micro heater of the chip bonding module is configured to be disposed on the push-type pin of the chip transferring module, the at least one micro heater of the chip bonding module is configured as the heat source generator for generating the heat source;
wherein, when the at least one micro heater of the chip bonding module is configured to be adjacent to the push-type pin of the chip transferring module, the at least one micro heater of the chip bonding module is configured as the light source generator for generating the light source;
wherein, when the chip transferring module is optionally configured to be used, the chip transferring module is allowed to be configured to sequentially transfer the chips carried by the flexible substrate to the circuit substrate through the push-type pins controlled by the signal control module, thereby allowing each of the chips to be electrically connected to the circuit substrate through at least two corresponding ones of a plurality of soldering materials;
wherein, when the chip bonding module is optionally configured to be used, the at least one micro heater of the chip bonding module is allowed to be configured to heat a corresponding one of the chips through the signal control module, thereby transferring a thermal energy generated by the at least one micro heater to the corresponding one of the chips;
wherein, when the chips are sequentially transferred to the circuit substrate through the chip transferring module, the chip bonding module is allowed to be configured to be disposed above the temporary carrying substrate, and the at least one micro heater of the chip bonding module is allowed to be configured to heat the corresponding one of the chips through the signal control module, thereby allowing each of the chips to be bonded on the circuit substrate through the at least two corresponding ones of the soldering materials that have been heated and then cooled;
wherein, when the temporary carrying substrate is configured to carry the chips, the chips are adhered to the temporary carrying substrate through an adhesive layer.

8. The chip transferring and bonding device according to claim 5,
wherein, when the substrate carrying module is optionally configured to be used, the substrate carrying module is allowed to be configured to carry a circuit substrate through the signal control module;
wherein, when the chip transferring module is optionally configured to be used, the chip transferring module is allowed to be configured to carry a temporary carrying substrate that is configured for carrying a plurality of chips through the signal control module;
wherein the at least one micro heater is not be disposed inside or outside the temporary carrying substrate;
wherein the chip transferring module includes a chip suction nozzle configured to suction the chip, and the temporary carrying substrate is a non-flexible substrate or a flexible substrate;
wherein the at least one micro heater of the chip bonding module is configured to be disposed on the chip suction nozzle of the chip transferring module or configured to be adjacent to the chip suction nozzle of the chip transferring module;
wherein, when the at least one micro heater of the chip bonding module is configured to be disposed on the chip suction nozzle of the chip transferring module, the at least one micro heater of the chip bonding module is configured as the heat source generator for generating the heat source;
wherein, when the at least one micro heater of the chip bonding module is configured to be adjacent to the chip suction nozzle of the chip transferring module, the at least one micro heater of the chip bonding module is configured as the light source generator for generating the light source;
wherein, when the chip transferring module is optionally configured to be used, the chip transferring module is allowed to be configured to sequentially transfer the chips carried by the non-flexible substrate or the flexible substrate to the circuit substrate through the chip suction nozzle controlled by the signal control module, thereby allowing each of the chips to be electrically connected to the circuit substrate through at least two corresponding ones of a plurality of soldering materials;
wherein, when the chip bonding module is optionally configured to be used, the at least one micro heater of the chip bonding module is allowed to be configured to heat a corresponding one of the chips through the signal control module, thereby transferring a thermal energy generated by the at least one micro heater to the corresponding one of the chips;
wherein, when the chips are sequentially transferred to the circuit substrate through the chip transferring module, the at least one micro heater of the chip bonding module is allowed to be configured to heat the corresponding one of the chips through the signal control module, thereby allowing each of the chips to be bonded on the circuit substrate through the at least two corresponding ones of the soldering materials that have been heated and then cooled;
wherein, when one of the chips bonded on the circuit substrate is damaged and determined to be a damaged chip, the at least one micro heater corresponding to the damaged chip is allowed to be configured to heat the damaged chip through the signal control module, thereby allowing the damaged chip to be removed from the circuit substrate through the at least two corresponding ones of the soldering materials that have been heated;
wherein, after the damaged chip is removed from the circuit substrate, a new chip is transferred to the circuit substrate through the chip transferring module, and the at least one micro heater of the chip bonding module is allowed to be configured to heat the new chip through the signal control module, thereby allowing the new chip to be bonded on the circuit substrate through a plurality of new soldering materials that have been heated and then cooled;
wherein, when the temporary carrying substrate is configured to carry the chips, the chips are adhered to the temporary carrying substrate through an adhesive layer.

9. A chip transferring and bonding device, comprising:
a signal control module;
a substrate carrying module configured to be electrically connected to the signal control module;
a chip transferring module configured to be electrically connected to the signal control module; and
a chip bonding module configured to be electrically connected to the signal control module, wherein the chip bonding module includes at least one micro heater;
wherein, when the substrate carrying module is optionally configured to be used, the substrate carrying module is allowed to be configured to carry the chip bonding module through the signal control module;
wherein, when the chip bonding module is optionally configured to be used, the chip bonding module is configured to carry a temporary carrying substrate that is configured for carrying a plurality of chips;
wherein, when the chip transferring module is optionally configured to be used, the chip transferring module is allowed to be configured to carry a circuit substrate through the signal control module;
wherein, when the chip transferring module is optionally configured to be used, the chip transferring module is allowed to be configured to transfer the circuit substrate to the chips that are carried by the temporary carrying substrate through the signal control module;
wherein, when the chip bonding module is optionally configured to be used, the at least one micro heater of the chip bonding module is allowed to heat a corresponding one of the chips through the signal control module.

10. The chip transferring and bonding device according to claim 9,
wherein, when the chip bonding module includes a plurality of micro heaters, the micro heaters are disposed on a carrier substrate of the chip bonding module and respectively correspond to the chips, and the micro heaters are not disposed inside or outside the temporary carrying substrate;
wherein each of the micro heaters of the chip bonding module is a heat source generator configured for generating a heat source;
wherein, when the chip transferring module is optionally configured to be used, the chip transferring module is allowed to be configured to transfer the circuit substrate to the chips through the signal control module, thereby allowing each of the chips to be electrically connected to the circuit substrate through at least two corresponding ones of a plurality of soldering materials;
wherein, when the chip bonding module is optionally configured to be used, each of the micro heaters of the chip bonding module is allowed to be configured to optionally heat the corresponding one of the chips through the signal control module, thereby simultaneously transmitting a thermal energy generated by all of the micro heaters to all of the chips or simultaneously transmitting a thermal energy generated by some of the micro heaters to some of the chips;
wherein, when the circuit substrate is transferred to the chips through the chip transferring module, the chip bonding module is configured to be disposed under the temporary carrying substrate, and the micro heaters of the chip bonding module are allowed to be configured to respectively heat the chips through the signal control module, thereby allowing each of the chips to be bonded on the circuit substrate through the at least two corresponding ones of the soldering materials that have been heated and then cooled;
wherein, when the temporary carrying substrate is configured to carry the chips, the chips are adhered to the temporary carrying substrate through an adhesive layer, and a predetermined arrangement shape formed by the chips corresponds to a predetermined arrangement shape formed by the micro heaters.
